(19) United States
(12) Patent Application Publication
(10) Pub. No.: US 2005/0136669 A1
(43) Pub. Date: Jun. 23, 2005

(54) Slurry for color photoresist planarization

(75) Inventors: Chia-Hao Lee, Kaohsiung (TW); Wen-Cheng Liu, Kaohsiung (TW); Deng-Yann Huoh, Kaohsiung Hsien (TW)

Correspondence Address: SCULLY SCOTT MURPHY & PRESSER, PC, 400 GARDEN CITY PLAZA, SUITE 300, GARDEN CITY, NY, 11530, US

(73) Assignee: Eternal Chemical Co., Ltd., Kaohsiung (TW)

(21) Appl. No.: 10/848,019

(22) Filed: May 18, 2004

(30) Foreign Application Priority Data
Dec. 19, 2003 (CN) 092136255

(51) Int. Cl. H01L 21/302; H01L 21/461

(52) U.S. Cl. 438/690

(57) ABSTRACT

The present invention relates to a chemical mechanical abrasive slurry for polishing a color photoresist, comprising composite abrasive particles and an aqueous medium. The abrasive slurry of the present invention can effectively polish off horn-like protuberances color filter processing.

### FIELD OF THE INVENTION

The invention relates to a chemical mechanical abrasive slurry which can be effectively used in polishing color photoresist.

### DESCRIPTION OF THE RELATED ART

The formation of color images on liquid crystal display panels mainly depends on the function of color filters. Back light source turns into gray scale light when passing through liquid crystals and by the control of driving IC. When the gray scale light travels through the color filter which is coated with red, green and blue color photoresists, the light turns into red, green and blue lights which are mixed to form color images in our eyes.

During the production of a color filter, when the red, green and blue color photoresist have been formed, they should be dried in vacuum. After the completeness of the drying step, horn-like protuberances will be generated on the photoresist and should be removed by polishing to improve the flatness of the photoresist. The improvement on the flatness of the photoresist can avoid circuit breaking during the preparation of conductive glass (e.g. ITO) circuits, and eliminate light scattering so as to enhance brightness.

Most of the abrasive slurries currently used for polishing color photoresists utilize aluminum oxide as abrasive particles. However, shadow and scratch may be left on the polished surfaces of the photoresists as a result of the irregular shapes of the aluminum oxide particles. Furthermore, the abrasive particles in most abrasive slurries are generally easy to precipitate.

Upon extensive research, it is found that by utilizing an abrasive slurry comprising composite silicon oxide particles coated with aluminum oxide with smaller particle sizes, no shadow or scratch will be left on the polished surfaces of the photoresists. Moreover the resultant slurry exhibits good flowability, which prevents the abrasive particles from precipitation and avoid the residue of the abrasive particles, and can effectively avoid the above-mentioned disadvantages encountered in traditional chemical abrasive slurries.

### SUMMARY OF THE INVENTION

The object of this invention is to provide a chemical mechanical abrasive slurry, characterized by comprising composite abrasive particles consisting of silicon oxide particles coated with aluminum oxide.

Another object of this invention is to provide a chemical mechanical abrasive slurry for polishing color photoresist which comprises composite abrasive particles and an aqueous medium, wherein the composite abrasive particles are silicon oxide particles coated with aluminum oxide.

Still another object of this invention is to provide a chemical mechanical abrasive slurry for polishing color photoresists during the production of liquid crystal display panels, which comprises composite abrasive particles and an aqueous medium, wherein the composite abrasive particles are silicon oxide particles coated with aluminum oxide.

### DETAILED DESCRIPTION OF THE INVENTION

The invention provides a chemical mechanical abrasive slurry, characterized by comprising composite abrasive particles consisting of silicon oxide particles coated with aluminum oxide.

The amount of the composite abrasive particles used in this invention, based on the total weight of the abrasive slurry, is in the range of 0.1% to 20% by weight.

Apart from the composite abrasive particles, the remaining component of the chemical mechanical abrasive slurry of this invention is an aqueous medium, with a pH value ranging from 5 and 9.

The aqueous medium used in this invention is well known to those skilled in the art. For example, water, preferably deionized water may be used in the preparation of the slurry.

The invention further provides a chemical mechanical abrasive slurry for polishing color photoresist, which comprises composite abrasive particles and an aqueous medium, wherein the composite abrasive particles are silicon oxide particles coated with aluminum oxide.

The invention further provides a chemical mechanical abrasive slurry for polishing color photoresists during the production of liquid crystal display panels, which comprises composite abrasive particles and an aqueous medium, wherein the composite abrasive particles are silicon oxide particles coated with aluminum oxide.

The amount of the composite abrasive particles used in this invention, based on the total weight of the abrasive slurry of this invention, is in the range of 0.1% to 20% by weight, preferably 0.1% to 10% by weight.

The composite abrasive particles of this invention are silicon oxide particles coated with aluminum oxide, and the particle size of said particles ranges from 50 nm and 150 nm, smaller than that of commonly used aluminum oxide particles (normally in the range from 200 nm and 500 nm). The abrasive slurry of this invention can provide the polished surfaces of photoresists with better flatness and reduced. In addition, the abrasive slurry exhibits good flowability, and thus avoid any precipitation and residue of the abrasive particles.

Preferably, the chemical mechanical abrasive slurry of this invention has a pH value ranging from 5 to 9.

The aqueous medium used in this invention is well known to those skilled in the art. For example, water; preferably deionized water may be used in the preparation of the slurry.

### BRIEF DESCRIPTION OF THE DRAWINGS

FIG. 1 is a transmission electronic microscope (TEM) picture of common aluminum oxide abrasive particles. As shown in the Figure, the particles have a diameter of about 300 nm and irregular shapes.

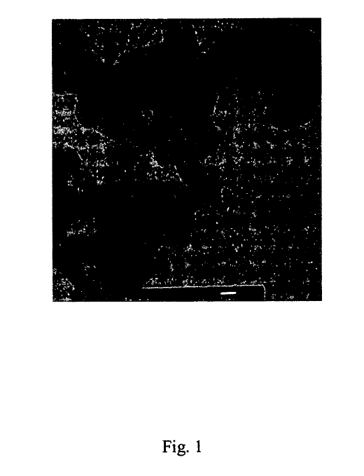

FIG. 2 is a TEM picture of the abrasive particles of this invention. The particles have a diameter of about 50 nm, are oval-shaped and not significantly different from each other in the particle size.

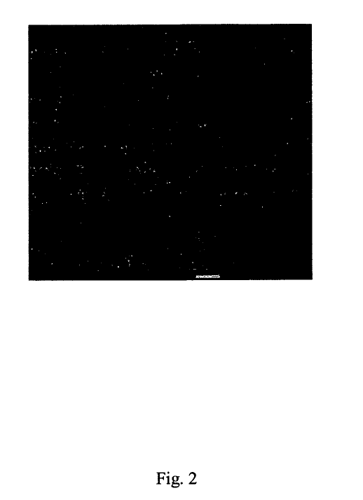

FIG. 3 is an atomic force microscope (AFM) picture of the photoresist after being polished by common abrasive particles, which shows a roughness of 29.51 nm.

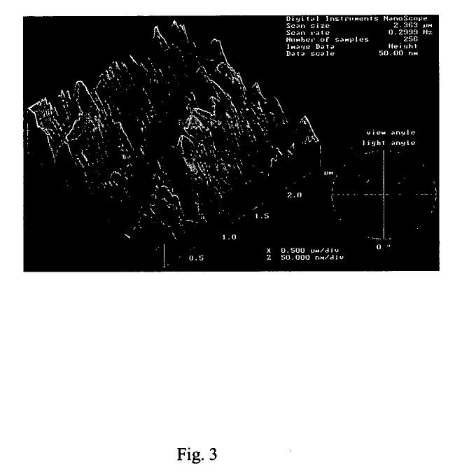

FIG. 4 is an AFM picture of the photoresist after being polished by the abrasive particles of this invention, which shows a roughness of 10.21 nm.

As demonstrated by the test results, when said photoresist is polished by the abrasive particles of this invention, the surface roughness of the polished photoresist can be significantly reduced from 29.51 nm to 10.21 nm.

The invention will be further illustrated in the following examples but not be limited to the scope of the working examples. Any modifications or changes, e.g., first concentrating then diluting the slurry to alter composition of the slurry, obvious to persons skilled in the art are within the scope of this invention.

### EXAMPLES

Polishing Test
A. Instrument: IPEC/Westech 472
B. Condition: Pressure: 2 psi
   Back Pressure: 0 psi
   Temperature: 30° C.
   Spindle Speed: 20 rpm
   Platen Speed: 25 rpm
   Pad Type: Rodel POLITEX
   Slurry Velocity: 150 ml/min.
C. Wafer: Silicon oxide thin film and silicon nitride thin film deposited by LPCVD on 6-inch silicon wafers, commercially available from Silicon Valley Microelectronics. Inc.
D. Photoresist: Red, Green and Blue color photoresist commercially available from JSR
   Polishing Test Procedure

Both before and after polishing, the thickness of the films should be measured by a surface profiler. The invention uses Model P-11 Surface Profiler of KLA-Tencor Company to determine the film thickness of the red, green and blue color photoresist. When measuring the polishing rate, photoresists are coated uniformly on the surface of a 6-inch wafer by spin coating, and then a straight line is drawn from the center to the edge using a diamond pencil to obtain the film thickness T₁ before polishing. After being polished by the exemplified slurries for 1.5 minutes and washed by ultra-pure water, the surfaces of the wafers were spray dried by high-pressure air. The thickness of the polished film (T₂) is measured by Model P-11 Surface Profiler. The polishing rate of the color photoresist is calculated from (T₁-T₂)/1.5.

Experimental Steps
(1) An abrasive slurry having a pH value of about 6.3,which comprises silicon oxide composite particles coated with a layer of aluminum oxide (original solids content: 20 wt %), was mixed with ultra-pure water at the mixing ratios of 1:10, 1:8 and 1:4. After mixing, the abrasive particles content were 2, 2.5 and 5 wt %, respectively.
(2) The film thickness before polishing was measured by P-11.
(3) Polishing test was performed on the wafers uniformly coated with color photoresist by IPEC/Westech 472.
(4) The polished surfaces of wafers were washed by ultra-pure water, and then dried with high-pressure air.
(5) The thickness of the film after polishing was measured by P-11 and the polishing rate of the color photoresist was calculated.

### Examples 1 to 4

Abrasive slurries with compositions shown in Table 1 below were prepared. The prepared abrasive slurries were used to polish color photoresist and the effects of slurries on the surfaces of photoresist were observed. The results are shown in Table 1.

TABLE 1

| Example | | Removal Rate of |
|---|---|---|
| No. | Composition of Abrasive Slurry | Photoresist (Å/min) |
| Example 1 | 2 wt % composite abrasive particles + | 3300 |
| | deionized water | |
| Example 2 | 2.5 wt % composite abrasive | 3500 |
| | particles + deionized water | |
| Example 3 | 5 wt % composite abrasive particles + | 3800 |
| | deionized water by weight | |
| Example 4 | 2 wt % aluminum oxide + deionized | 1500 |
| | water by weight | |

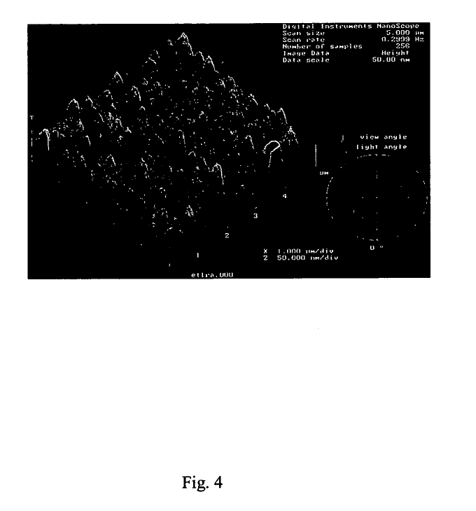

As shown by the data in Table 1, the abrasive particles of silicon oxide particles coated with aluminum oxide will increase the removal rate of the photoresist by at least 2 times. Moreover, according to FIG. 4, the flatness of the photoresist surfaces polished by the abrasive particles of this invention is better than that polished by aluminum oxide particles. As a result, the abrasive slurry of this invention can provide a wider spectrum of applications.

1. (canceled)

2. A chemical mechanical polishing process for polishing a color photoresist, said process comprising polishing the color photoresist with an abrasive slurry comprising composite abrasive particles and an aqueous medium, wherein the composite abrasive particles are silicon oxide particles coated with aluminum oxide.

3. The process according to claim 2, wherein said abrasive slurry comprises 0.1% to 20% by weight of the composite abrasive particles.

4. The process according to claim 2, wherein said abrasive slurry has a pH value ranging from 5 to 9.

5. The process according to claim 2, wherein said aqueous medium is deionized water.
